(19) United States
(12) Patent Application Publication
(10) Pub. No.: US 2006/0107973 A1
(43) Pub. Date: May 25, 2006

(54) Endpoint detector and particle monitor

(76) Inventor: Samuel Leung, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/249,025

(22) Filed: Oct. 11, 2005

Related U.S. Application Data
(60) Provisional application No. 60/617,998, filed on Oct. 12, 2004.

(51) Int. Cl. B08B 5/04; B08B 9/00; B05C 11/00; C23C 16/00

(52) U.S. Cl. 134/21; 134/22.1; 118/715; 118/712

(57) ABSTRACT

A substrate processing system, which includes a vacuum deposition process chamber having an exhaust outlet configured to discharge one or more particles during a deposition cycle and cleaning gas reactants during a cleaning cycle and an in-situ particle monitor coupled to the exhaust outlet. The in-situ particle monitor is configured to determine a starting point of the cleaning cycle. The plasma enhanced chemical vapor deposition system further includes an infrared endpoint detector assembly coupled to the exhaust outlet. The infrared endpoint detector assembly is configured to determine an endpoint of the cleaning cycle.

### CROSS-REFERENCE TO RELATED APPLICATIONS

This application claims benefit of U.S. provisional patent application Ser. No. 60/617,998, filed Oct. 12, 2004, which is herein incorporated by reference.

### BACKGROUND OF THE INVENTION

1. Field of the Invention

Embodiments of the present invention generally relate to chemical vapor deposition (CVD) processing, and more particularly, to a method and system for cleaning a CVD chamber.

2. Description of the Related Art

Chemical vapor deposition (CVD) is widely used in the semiconductor industry to deposit films of various kinds, such as intrinsic and doped amorphous silicon (a-Si), silicon oxide (SiₓO_{y}), silicon nitride (SiᵣNₛ), silicon oxynitride, and the like on a substrate. Modern semiconductor CVD processing is generally done in a vacuum chamber by using precursor gases which dissociate and react to form the desired film. In order to deposit films at low temperatures and relatively high deposition rates, a plasma may be formed from the precursor gases in the chamber during the deposition. One type of such plasma processes is plasma enhanced CVD (PECVD). Another type of such plasma processes is HDP-CVD.

State of the art CVD semiconductor processing chambers are made of aluminum and include a support for the substrate and a port for entry of the required precursor gases. When a plasma is used, the gas inlet and/or the substrate support is connected to a source of power, such as a radio frequency (RF) power source. A vacuum pump is also connected to the chamber to control the pressure in the chamber and to remove the various gases and contaminants generated during the deposition.

In all semiconductor processing, contaminants in the chamber must be kept to a minimum. During the deposition process, the film is deposited not only on the substrate, but also on walls and various components, e.g., shields, the substrate support and the like, in the chamber. During subsequent depositions, the film on the walls and various components can crack or peel, causing contaminants to fall on the substrate. This causes problems and damage to particular devices on the substrate. Damaged devices have to be discarded.

When large glass substrates, e.g., 370 mm×470 mm or larger, are processed to form thin film transistors for use as computer screens and the like, more than a million transistors may be formed on a single substrate. The presence of contaminants in the processing chamber is even more serious in this case, since the computer screen and the like will be inoperative if damaged by particulates. In this case, an entire large glass substrate may have to be discarded.

Thus, the CVD chamber must be periodically cleaned to remove accumulated films from prior depositions. Cleaning is generally done by passing an etch gas, particularly a fluorine-containing gas, such as nitrogen trifluoride (NF₃), into the chamber. A standard method of performing this cleaning procedure is to pass a constant flow of NF₃ into the chamber. A plasma is initiated from the fluorine-containing gas which reacts with coatings from prior depositions on the chamber walls and fixtures, e.g., coatings of Si, SiₓO_{y}, SiᵣNₛ, SiON and the like, as well as any other materials in the chamber. In particular, the NF₃ creates free fluorine radicals “F*” which react with Si-containing residues.

Currently, the frequency and duration of a cleaning cycle are typically determined by trial and error or historical data. For instance, a chamber may be scheduled for cleaning after processing a predetermined number of substrates, regardless of the condition of the chamber. With respect to duration, an extra 20 to 30 percent of clean time are typically added to the cleaning cycle, without regard to considering the damage that the extra clean time may cause to the chamber and the components contained therein.

Therefore, a need exists in the art for an improved method and system for controlling a cleaning cycle of a PECVD system configured to process flat panel display substrates.

### SUMMARY OF THE INVENTION

One or more embodiments of the invention are directed to a substrate processing system. The substrate processing system includes a vacuum deposition process chamber having an exhaust outlet configured to discharge one or more particles during a deposition cycle and cleaning gas reactants during a cleaning cycle and an in-situ particle monitor coupled to the exhaust outlet. The in-situ particle monitor is configured to determine a starting point of the cleaning cycle. The plasma enhanced chemical vapor deposition system further includes an infrared endpoint detector assembly coupled to the exhaust outlet. The infrared endpoint detector assembly is configured to determine an endpoint of the cleaning cycle.

One or more embodiments of the invention are directed to a method for controlling a cleaning cycle of a substrate processing system. The method includes determining a starting point of the cleaning cycle using an in-situ particle monitor coupled to an exhaust outlet of a vacuum deposition process chamber during a deposition cycle, initiating the cleaning cycle inside the vacuum deposition process chamber once the starting point of the cleaning cycle is determined, determining an endpoint of the cleaning cycle using an infrared endpoint detection assembly coupled to the exhaust outlet, and ending the cleaning cycle once the endpoint of the cleaning cycle is determined.

One or more embodiments of the invention are directed to a gas detection system. The gas detection system includes an in-situ particle monitor adapted for coupling to an exhaust outlet, wherein the in-situ particle monitor is configured to determine a starting point of a cleaning cycle; and an infrared endpoint detector assembly adapted for coupling to the exhaust outlet, wherein the infrared endpoint detector assembly is configured to determine an endpoint of the cleaning cycle. In another embodiment the infrared endpoint detector comprises a housing having sidewalls defining a through-hole for the passage of a gas wherein the sidewalls include windows; an infrared source coupled to the housing for generating an infrared light and transmitting the infrared light through the windows so that the infrared light passes through the through-hole; and an infrared detector coupled to the housing wherein the infrared detector is positioned to receive the infrared light passing through the window. In another embodiment the in-situ particle monitor is configured to determine the starting point by monitoring a total number of particles flowing through the exhaust outlet during a deposition cycle. In another embodiment the in-situ particle monitor initiates the cleaning cycle upon completion of the deposition cycle when the total number of particles exceeds a predetermined value. In another embodiment the predetermined value of the gas detection system is about 10,000 particles.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic cross-sectional view of one embodiment of a plasma enhanced chemical vapor deposition system.

FIG. 2 illustrates a schematic cross-sectional view of another embodiment of a plasma enhanced chemical vapor deposition system.

FIG. 3 illustrates a schematic diagram of a gas detector in accordance with one or more embodiments of the invention.

FIG. 4 illustrates a flow diagram of a method for controlling a cleaning cycle of the plasma enhanced chemical vapor deposition system in accordance with one or more embodiments of the invention.

### DETAILED DESCRIPTION

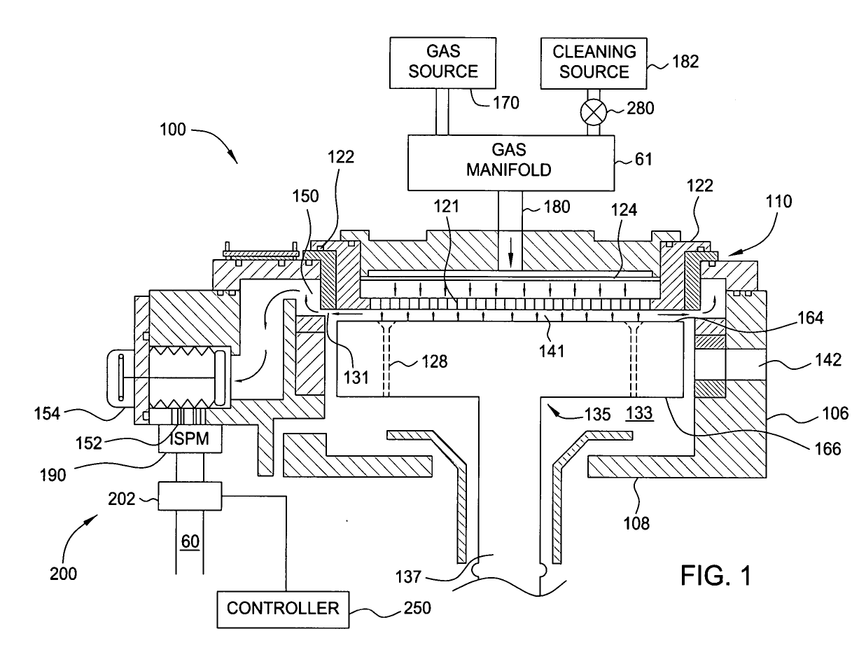

FIG. 1 illustrates a schematic cross-sectional view of one embodiment of a plasma enhanced chemical vapor deposition (PECVD) system 100, which may be available from AKT, a division of Applied Materials, Inc., of Santa Clara, Calif. The PECVD system 100 may be used in cluster process systems, in-line systems, stand-alone systems and the like. The PECVD system 100 includes a vacuum deposition process chamber 133. The process chamber 133 has walls 106 and a bottom 108 that partially define a processing region 141. The walls 106 and the bottom 108 are typically fabricated from a unitary block of aluminum or other material compatible with processing. The walls 106 has an opening 142 for transferring flat panel display substrates into and out of the process chamber 133. Examples of flat panel display substrates include glass substrates, polymer substrates and the like.

A temperature controlled substrate support assembly 135 is centrally disposed within the processing chamber 133. The support assembly 135 is configured to support a flat panel display substrate during processing. The substrate support assembly 135 may have an aluminum body that encapsulates at least one embedded heater (not shown). The heater, such as a resistive element, disposed in the support assembly 135, is coupled to an optional power source and controllably heats the support assembly 135 and the flat panel display substrate positioned thereon to a predetermined temperature. Typically, in a CVD process, the heater maintains the flat panel display substrate at a uniform temperature between about 150 to at least about 460 degrees Celsius, depending on the deposition processing parameters for the material being deposited.

Generally, the support assembly 135 has a lower side 166 and an upper side 164. The upper side 164 is configured to support the flat panel display substrate. The lower side 166 has a stem 137 coupled thereto. The stem 137 couples the support assembly 135 to a lift system (not shown) that moves the support assembly 135 between an elevated processing position and a lowered position that facilitates substrate transfer to and from the processing chamber 133. The stem 137 additionally provides a conduit for electrical and thermocouple leads between the support assembly 135 and other components of the system 100.

A bellows (not shown) may be coupled between the support assembly 135 and the bottom 108 of the processing chamber 133. The bellows provides a vacuum seal between the processing region 141 and the atmosphere outside the processing chamber 133 while facilitating vertical movement of the support assembly 135.

The support assembly 135 may additionally support a circumscribing shadow frame (not shown). Generally, the shadow frame is configured to prevent deposition at the edge of the flat panel display substrate and the support assembly 135 so that the substrate does not stick to the support assembly 135. The support assembly 135 has a plurality of holes 128 disposed therethrough that are configured to accept a plurality of lift pins (not shown). The lift pins are typically comprised of ceramic or anodized aluminum. The lift pins may be actuated relative to the support assembly 135 by an optional lift plate (not shown) to project from the support surface (not shown), thereby placing the substrate in a spaced-apart relation to the support assembly 135.

The processing chamber 133 further includes a lid assembly 110, which provides an upper boundary to the processing region 141. The lid assembly 110 typically can be removed or opened to service the processing chamber 133. The lid assembly 110 may be fabricated from aluminum (Al). The lid assembly 110 includes an exhaust plenum 150, which is configured to channel gases and processing by-products uniformly from the processing region 141 and out of the processing chamber 133.

The lid assembly 110 typically includes an entry port 180 through which processing and cleaning gases are introduced into the processing chamber 133 through a gas manifold 61. The gas manifold 61 is coupled to a processing gas source 170 and a cleaning gas source 182. The cleaning gas source 182 typically provides a cleaning agent, such as fluorine radicals, that is introduced into the processing chamber 133 to remove deposition by-products and films from processing chamber hardware. NF₃ may be used as the cleaning gas to provide the fluorine radicals. Other cleaning gases, such as CF₄, C₂F₆, SF₆ and the like, may also be used to provide the fluorine radicals. The cleaning gas source 182 may be a remote plasma clean source configured to generate an etchant plasma. Such remote plasma clean source is typically remote from the processing chamber 133 and may be a high density plasma source, such as a microwave plasma system, toroidal plasma generator or similar device.

In one embodiment, a valve 280 may be disposed between the clean source 182 and the gas manifold 61. The valve 280 is configured to selectively allow or prevent cleaning gases from entering the gas manifold 61. During cleaning, the valve 280 is configured to allow the cleaning gases from the cleaning gas source 182 to pass into gas manifold 61, where they are directed through the entry port 180 then through a perforated blocker plate 124 and into the processing region 141 to etch the inner chamber walls and other components contained therein. During deposition, the valve 280 is configured to prevent cleaning gases from passing into the gas manifold 61. In this manner, the valve 280 isolates the clean processes from the deposition processes.

The processing chamber 133 further includes a gas distribution plate assembly 122 coupled to an interior side of the lid assembly 110. The gas distribution plate assembly 122 may have substantially the same surface area as the flat panel display substrate. The gas distribution plate assembly 122 includes a perforated area 121 through which processing and cleaning gases are delivered to the processing region 141. The perforated area 121 of the gas distribution plate assembly 122 is configured to provide uniform distribution of gases passing through the gas distribution plate assembly 122 into the processing chamber 133.

In operation, processing gases flow into the processing chamber 133 through a gas manifold 61 and the entry port 180. The gases then flow through the perforated area 121 of the gas distribution plate assembly 122 into the processing region 141. An RF power supply (not shown) may be used to apply electrical power between the gas distribution plate assembly 122 and the support assembly 135 to excite the processing gases mixture to form a plasma. The constituents of the plasma react to deposit a desired film on the surface of the substrate on the support assembly 135. The RF power is generally selected commensurate with the size of the substrate to drive the chemical vapor deposition process.

The processing gases may be exhausted from the process chamber 133 through a slot-shaped orifice 131 surrounding the processing region 141 into the exhaust plenum 150. From the exhaust plenum 150, the gases flow by a vacuum shut-off valve 154 and into an exhaust outlet 152 which comprises a discharge conduit 60 that connects to an external vacuum pump (not shown).

In accordance with one embodiment of the invention, an infrared endpoint detection assembly 200 is mounted underneath the exhaust outlet 152. The infrared endpoint detection assembly 200 is configured to determine the endpoint of a cleaning cycle by detecting changes in light intensity that occur due to absorbance of light by the exhausted cleaning gas reactants, such as SiF₄. The infrared endpoint detection assembly 200 may be used with either an in situ plasma or remote plasma.

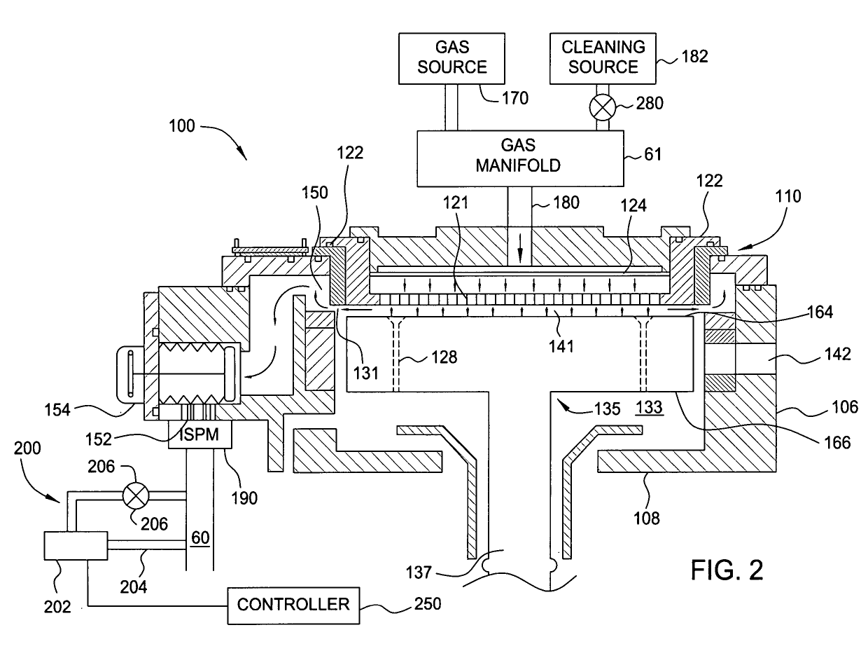

The infrared endpoint detection assembly 200 includes a gas detector 202 positioned along the discharge conduit 60. In one embodiment, the gas detector 202 is positioned along a bypass line 204 that receives a sample stream of gas from the conduit 60, as shown in FIG. 2. In this embodiment, the bypass line 204 may include a control valve 206 to vary the amount of flow passing through line 204, or to completely cease gas flow along the bypass line 204, for example, during deposition.

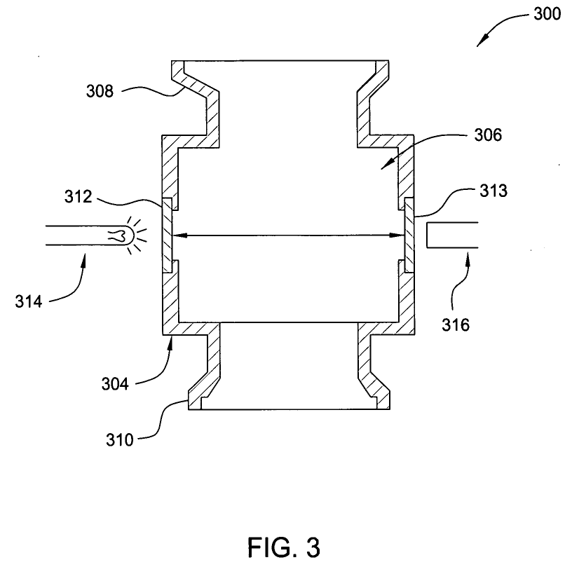

FIG. 3 illustrates a schematic diagram of a gas detector 300 in accordance with one or more embodiments of the invention. As shown in FIG. 3, the gas detector 300 includes a housing 304 defining a through-hole 306 in communication with the conduit 60 for allowing gases and other residue from the processing chamber 133 to pass therethrough. A pair of flanges 308, 310 preferably attach the housing 304 to the conduit 60. The side walls of the housing 304 include a pair of infrared (IR) windows 312, 313 that are configured to allow far infrared light to pass through. Far infrared light has wavelength starting at about 10 μm. Infrared windows 312, 313 are spaced by a length L and preferably comprise a material substantially transparent to far infrared light such that zero or substantially little of the light is absorbed by windows 312, 313. In addition, the infrared window 312, 313 material should be process-compatible, inert with respect to the processing and cleaning gas chemistry, and the material should not contaminate the film. In embodiments where fluorine radicals are used for the cleaning process, windows 312 and 313 are resistant to fluorine. The infrared windows 312, 313 may be made from materials such as germanium, calcium fluoride, or the like.

The detector 300 further includes a far infrared source 314 suitably coupled to the housing 304 for generating far infrared light and transmitting this light through windows 312, 313 so that the light passes through through-hole 306. An infrared detector 316 is coupled to the housing 304 in position to receive and detect the far infrared light passing through the window 313. The far infrared source 314 may be a tungsten lamp source with an optical notch filter.

When the infrared endpoint detection assembly 200 is in use, the cleaning gas reactants (e.g., SiF₄) are directed along the conduit 60 and the through-hole 306 of the detector 300. The far infrared source 314 transmits far infrared light through window 312, through-hole 306 and window 313, where it is received by the detector 316. As the light passes through the cleaning gas SiF₄ reactants, these reactants (i.e., the silicon) absorb a portion of the far infrared light, which reduces the light intensity received by detector 316. The fluorine does not absorb the far infrared light. Therefore, when the detected far infrared light intensity increases up to a reference value, the detector 316 sends a signal to a controller 250 indicating that the concentration of SiF₄ passing through the conduit 60 has substantially diminished or completely stopped, which indicates that the cleaning cycle endpoint has arrived. At this point, the controller 250 may send an appropriate signal to a processor (not shown) to close the valve 280 to prevent further etchant gases from entering the chamber. In the above exemplary clean process, the endpoint detection system 200 utilizes infrared source 314 to provide, and the detector 316 to detect, far infrared wavelengths that can be absorbed by cleaning gas reactants SiF₄, which absorb light of a predetermined wavelength, e.g., 10 μm, and fluorine, which absorbs light with a wavelength of about 5-6 μm. In other embodiments, the infrared source 314 and the detector 316 can provide light at different wavelengths, depending on the light absorbance characteristics of the specific cleaning gas reactants utilized in the clean cycle.

By way of example, Iₒ is the intensity of the infrared light when no SiF₄ is flowing through the conduit 60 and the detector 316 receives the full intensity from the infrared source 314. As SiF₄flows through the through-hole 306 during cleaning, the far infrared light is absorbed and the intensity received by the detector 316 (I) is reduced, given by the expression:
I/I₀=exp(−X*L*C),
where X is the extinction coefficient of IR windows 312, 313 or a filter (not shown), L is the length between windows 312, 313 and C is the concentration of SiF₄ passing through the detector 300. As I/Iₒ approaches the value 1, the SiF₄ concentration is diminishing, which means that the cleaning endpoint is approaching. The controller 250 continuously monitors I/Iₒ, until this value approaches 1, which indicates that the cleaning endpoint has arrived. Details of the infrared endpoint detection assembly 200 maybe found in commonly assigned U.S. Pat. No. 5,879,574, which is incorporated herein by reference in its entirety. Although one or more embodiments of the invention have been described with reference to an infrared endpoint detection assembly, other types of chemical detectors capable of detecting exhausted cleaning gas reactants are also contemplated by other embodiments of the invention.

In accordance with another embodiment of the present invention, an in-situ particle monitor (ISPM) 190 is coupled to the exhaust outlet 152. The ISPM 190 is configured to monitor the number of particles passing through the exhaust outlet 152. The ISPM 190 may be commercially available from Pacific Scientific Instruments of Grants Pass, Oreg. The ISPM 190 may also be disposed along the discharge conduit 60 between the exhaust outlet 152 and the external vacuum pump or downstream of the external vacuum pump.

The ISPM 190 may include a light source, e.g., laser, a detector and a controller. The light source is configured to transmit a light beam across the discharge conduit 60. As a particle is discharged out of the exhaust outlet 152 through the ISPM 190, the particle interrupts the light beam and creates a scattered light. A portion of the scattered light is detected by the detector, which associates the scattered light with the presence of the particle intersecting the light beam. The detector is coupled to the controller, which is configured to count the number of particles passing through the ISPM 190. In one embodiment, the ISPM 190 is used to monitor the total number particles passing through the exhaust outlet 152 during deposition. When the total number of particles reaches a predetermined number (e.g., 10,000 particles), a cleaning cycle is initiated upon completion of the current deposition. In another embodiment, the ISPM 190 is used to monitor the total number of particles passing through the exhaust outlet 152 during cleaning. The total number of particles may provide an indication to the user (e.g., process engineer) as to the extent of cleanliness of the process chamber 133. Details of the ISPM 190 may be found in commonly assigned U.S. Pat. No. 5,271,264, which is incorporated herein by reference in its entirety.

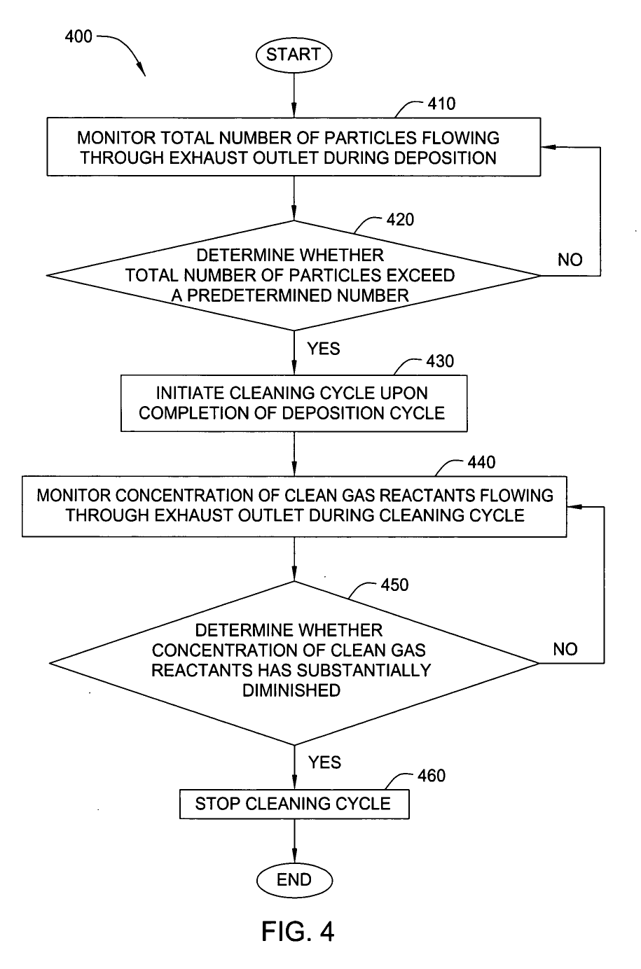

FIG. 4 illustrates a flow diagram of a method 400 for controlling a cleaning cycle of the plasma enhanced chemical vapor deposition system 100 in accordance with one or more embodiments of the invention. At step 410, the total number of particles flowing through the exhaust outlet 152 during a deposition cycle is monitored. In one embodiment, the number of particles flowing through the exhaust outlet 152 is monitored by the ISPM 190 coupled to the exhaust outlet 152. At step 420, a determination is made as to whether the total number of particles exceeds a predetermined number. The predetermined number may vary depending on the recipes, the types of gases, and the size of substrates used during deposition. In one embodiment, the predetermined number may be 10,000 particles. If the answer is in the negative, processing returns to step 410. If the answer is in the affirmative, then processing continues to step 430, at which a cleaning cycle is initiated upon completion of the deposition cycle. In this manner, the frequency of a cleaning cycle for the plasma enhanced chemical vapor deposition system 100 may be determined.

During the cleaning cycle, the amount or concentration of cleaning gas reactants (e.g., SiF₄) flowing through the exhaust outlet 152 may be monitored (step 440). In one embodiment, the amount of cleaning gas reactants is monitored by the infrared endpoint detection assembly 200 disposed along the discharge conduit 60. At step 450, a determination is made as to whether the amount of the cleaning gas reactants in the total amount of gas being discharged out of the exhaust outlet 152 has substantially diminished. In one embodiment, a determination is made as to whether the amount of cleaning gas reactants flowing through the exhaust outlet 152 is less than about five percent of the total amount of gas flowing through the exhaust outlet 152. If the answer is in the negative, then processing returns to step 440. If the answer is in the affirmative, then processing continues to step 460, at which the cleaning cycle is ended. In this manner, the duration of the cleaning cycle for the plasma enhanced chemical vapor deposition system 100 may be determined. Advantages of the various embodiments of the present invention include a reduction (e.g., about 5 to 30% reduction) in NF₃ gas usage during the cleaning cycle and increased throughput due to increased system utilization.

While the foregoing is directed to embodiments of the present invention, other and further embodiments of the invention may be devised without departing from the basic scope thereof, and the scope thereof is determined by the claims that follow.

What is claimed is:

1. A substrate processing system, comprising:
a vacuum deposition process chamber having an exhaust outlet configured to discharge one or more particles during a deposition cycle and cleaning gas reactants during a cleaning cycle;
an in-situ particle monitor coupled to the exhaust outlet, wherein the in-situ particle monitor is configured to determine a starting point of the cleaning cycle; and
an infrared endpoint detector assembly coupled to the exhaust outlet, wherein the infrared endpoint detector assembly is configured to determine an endpoint of the cleaning cycle.

2. The system of claim 1, wherein the in-situ particle monitor is configured to determine the starting point by monitoring a total number of particles flowing through the exhaust outlet during the deposition cycle.

3. The system of claim 1, wherein the in-situ particle monitor is configured to determine the starting point by monitoring a total number of particles flowing through the exhaust outlet during the deposition cycle; and initiating the cleaning cycle upon completion of the deposition cycle when the total number of particles exceeds a predetermined value.

4. The system of claim 3, wherein the predetermined value is about 10,000 particles.

5. The system of claim 1, wherein the infrared endpoint detector assembly is configured to determine the endpoint of the cleaning cycle by monitoring an amount of cleaning gas reactants in a total amount of gas flowing through the exhaust outlet during the cleaning cycle.

6. The system of claim 1, wherein the infrared endpoint detector assembly is configured to determine the endpoint of the cleaning cycle by monitoring an amount of cleaning gas reactants in a total amount of gas flowing through the gas outlet during the cleaning cycle; and ending the cleaning cycle when the amount of cleaning gas reactants flowing through the gas outlet is less than about five percent of the total amount of gas flowing through the gas outlet.

7. The system of claim 1, wherein the substrate processing system is a plasma enhanced chemical vapor deposition system for processing one or more flat panel display substrates.

8. A method for controlling a cleaning cycle of a substrate processing system, comprising:
determining a starting point of the cleaning cycle using an in-situ particle monitor coupled to an exhaust outlet of a vacuum deposition process chamber during a deposition cycle;
initiating the cleaning cycle inside the vacuum deposition process chamber once the starting point of the cleaning cycle is determined;
determining an endpoint of the cleaning cycle using an infrared endpoint detection assembly coupled to the exhaust outlet; and
ending the cleaning cycle once the endpoint of the cleaning cycle is determined.

9. The method of claim 8, wherein the starting point of the cleaning cycle is determined by monitoring a total number of particles flowing through the exhaust outlet during the deposition cycle.

10. The method of claim 8, wherein the starting point of the cleaning cycle is determined by:
monitoring a total number of particles flowing through the exhaust outlet during the deposition cycle; and
determining whether the total number of particles exceeds a predetermined value.

11. The method of claim 10, wherein initiating the cleaning cycle comprises initiating the cleaning cycle upon completion of the deposition cycle when it is determined that the total number of particles exceeds the predetermined value.

12. The method of claim 10, wherein the predetermined value is about 10,000 particles.

13. The method of claim 8, wherein determining the endpoint of the cleaning cycle comprises monitoring an amount of cleaning gas reactants in a total amount of gas flowing through the exhaust outlet during the cleaning cycle.

14. The method of claim 8, wherein determining the endpoint of the cleaning cycle comprises:
monitoring an amount of cleaning gas reactants in a total amount of gas flowing through the exhaust outlet during the cleaning cycle; and
determining whether the amount of cleaning gas reactants flowing through the exhaust outlet is less than about five percent of the total amount of gas flowing through the exhaust outlet.

15. The method of claim 13, wherein ending the cleaning cycle comprises ending the cleaning cycle when it is determined that the amount of cleaning gas reactants flowing through the exhaust outlet is less than about five percent of the total amount of gas flowing through the exhaust outlet.

16. A gas detection system comprising:
an in-situ particle monitor adapted for coupling to an exhaust outlet, wherein the in-situ particle monitor is configured to determine a starting point of a cleaning cycle; and
an infrared endpoint detector assembly adapted for coupling to the exhaust outlet, wherein the infrared endpoint detector assembly is configured to determine an endpoint of the cleaning cycle.

17. The gas detection system of claim 16, wherein the infrared endpoint detector assembly of claim 16 comprises:
a housing having sidewalls defining a through-hole for the passage of a gas wherein the sidewalls include windows;
an infrared source coupled to the housing for generating an infrared light and transmitting the infrared light through the windows so that the infrared light passes through the through-hole; and
an infrared detector coupled to the housing wherein the infrared detector is positioned to receive the infrared light passing through the window.

18. The gas detection system of claim 16, wherein the in-situ particle monitor is configured to determine the starting point by monitoring a total number of particles flowing through the exhaust outlet during a deposition cycle.

19. The gas detection system of claim 18, wherein the in-situ particle monitor initiates the cleaning cycle upon completion of the deposition cycle when the total number of particles exceeds a predetermined value.

20. The gas detection system of claim 19, wherein the predetermined value is about 10,000 particles.
